(19) United States
(12) Patent Application Publication
(10) Pub. No.: US 2026/0150442 A1
(43) Pub. Date: May 28, 2026

(54) LIGHT-EMITTING DEVICE HAVING EXCELLENT LIGHT EFFICIENCY AND MANUFACTURING METHOD THEREOF

(71) Applicant: Korea Photonics Technology Institute, Gwangju (KR)

(72) Inventors: Yung Ryel RYU, Irvine, CA (US); Jong Hyeob BAEK, Daejeon (KR); Sang Mook KIM, Gwangju (KR); Tae Hun JEONG, Gwangju (KR); Young Woo KIM, Gwangju (KR)

(73) Assignee: Korea Photonics Technology Institute, Gwangju (KR)

(21) Appl. No.: 19/448,351

(22) Filed: Jan. 14, 2026

Related U.S. Application Data
(63) Continuation of application No. PCT/KR2024/010078, filed on Jul. 15, 2024.

(30) Foreign Application Priority Data
Jul. 25, 2023 (KR) 10-2023-0096662
Aug. 16, 2023 (KR) 10-2023-0106792
Sep. 25, 2023 (KR) 10-2023-0128003
Apr. 5, 2024 (KR) 10-2024-0046343

(51) Int. Cl. H10H 20/84; H10H 20/01

(52) U.S. Cl. CPC H10H 20/84; H10H 20/034

(57) ABSTRACT

Disclosed are a light-emitting device having excellent light efficiency. A light-emitting device includes: a substrate; an n-type cladding layer deposited on the substrate and implemented with a semiconductor material doped with an n-type dopant; an active layer deposited on the n-type cladding layer, in which holes and electrons provided from the n-type cladding layer recombine to generate light; a p-type semiconductor layer deposited on the active layer and providing holes to the active layer; a protective layer implemented with a material in which a light transmittance in a visible-wavelength band and an electrical conductivity are respectively at least a predetermined first reference value and at least a predetermined second reference value, the protective layer being deposited on the p-type semiconductor layer to protect the p-type semiconductor layer from an outside environment; and electrodes respectively formed on the n-type cladding layer and on the protective layer.

### CROSS-REFERENCE TO RELATED APPLICATION

This application is a continuation of International Application No. PCT/KR 2024/010078, filed on Jul. 15, 2024, which claims priority, pursuant to U.S. patent law Section 119(a) (35 U.S.C. § 119(a)), to Korean Patent Application No. 10-2023-0096662 filed in Korea on Jul. 25, 2023; Korean Patent Application No. 10-2023-0106792 filed in Korea on Aug. 16, 2023; Korean Patent Application No. 10-2023-0128003 filed in Korea on Sep. 25, 2023; and Korean Patent Application No. 10-2024-0046343 filed in Korea on Apr. 5, 2024, the entire contents of all of which are incorporated herein by reference.

This patent application is based on research results supported by the National Research Foundation of Korea (NRF), funded by the Ministry of Science and ICT of the Republic of Korea in 2023 (Project Unique No.: 1711195422; Subproject No.: 2022M3H4A3A01082883; Project Title: Development of foundational technology for 5 μm-class InGaN red micro-LED surpassing 30% external quantum efficiency (EQE)).

### BACKGROUND

### 1. Technical Field

The present invention relates to a light-emitting device having excellent light efficiency and a method for manufacturing the same.

### 2. Related Art

Contents described in this part merely provide background information of the present embodiment, and do not constitute a conventional technology.

A light-emitting diode is an inorganic light source and is diversely used in various fields such as display devices, vehicle lamps, and general lighting. A light-emitting diode has advantages such as long lifespan, low power consumption, and fast response speed, and thus is rapidly replacing conventional light sources. A light-emitting diode can generally implement various colors by using a mixed color of blue, green, and red. Light-emitting diodes used in various devices include a plurality of pixels to implement various images or colors. Each pixel is provided with blue, green, and red sub-pixels. A color of the corresponding pixel is determined by a combination of these sub-pixels, and an image is implemented by a combination of the respective pixels.

Conventional light-emitting diodes have been typically manufactured based on nitride semiconductors. Nitride semiconductor-based light-emitting diodes have shown relatively superior light efficiency compared to those of other conventional materials. However, conventional nitride semiconductor-based light-emitting diodes structurally include the following problems.

First, a nitride semiconductor-based light-emitting diode has an internal pressure to compress or expand due to a difference in lattice constants of materials. Such internal pressure (strain) generates a piezo electric field inside an active layer, and the piezo electric field thus generated causes a problem of significantly decreasing internal light emission efficiency of the light-emitting device.

Another problem is caused by the fact that the density and mobility of holes injected into a p-type semiconductor layer are significantly lower than those of electrons injected into an n-type semiconductor layer. Due to this, the number of holes injected into the active layer is relatively significantly smaller than the number of electrons, so that excess electrons injected into the active layer are accumulated at an interface between the active layer and the p-type semiconductor layer. As such, the accumulated electrons generate another piezo electric field, thereby significantly reducing the probability that light is generated by combination of electrons and holes. Also, as an injection current increases, more electrons than holes are gathered in the active layer, so that internal quantum efficiency for generating light also gradually decreases.

As such, internal pressure is generated by the aforementioned mismatch of lattice constants and imbalance of hole particles and electron particles, and an electric field is generated inside the active layer by the generated internal pressure. The electric field generates a problem of obstructing the flow of injected hole particles and electron particles and obstructing the combination thereof to decrease the probability of light generation.

### SUMMARY

One object of an embodiment of the present invention is to provide a light-emitting device and a method for manufacturing the same, which have improved light efficiency by adjusting lattice constants and improving the density of holes, in order to reduce internal pressure generated by density imbalance between holes and electrons and lattice constant mismatch in an active layer.

One object of an embodiment of the present invention is to provide a light-emitting device and a method for manufacturing the same, which have improved light efficiency by having a hybrid type cladding layer implemented with different materials to reduce the generation of internal pressure and improve the density of holes.

One object of an embodiment of the present invention is to provide a light-emitting device and a method for manufacturing the same, which have improved light efficiency by having a cladding layer of a heterogeneous material such as zinc oxide (ZnO) to reduce the generation of internal pressure and improve the density of holes.

One object of an embodiment of the present invention is to provide a light-emitting device and a method for manufacturing the same, which include a reflective electrode having excellent reflectivity and thus have excellent light output.

Also, one object of an embodiment of the present invention is to provide a light-emitting device and a method for manufacturing the same, which have improved light output by making current flow uniform and minimizing obstruction of output light due to electrodes.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer; a protective layer implemented with a material of which light transmittance in a visible light wavelength band and electrical conductivity are respectively a preset first reference value and a preset second reference value or more, and deposited on the p-type semiconductor to protect the p-type semiconductor from the outside; and electrodes respectively formed on the n-type cladding layer and the protective layer.

According to one aspect of the present invention, provided is a method for manufacturing a light-emitting device, comprising: a deposition process of sequentially depositing an n-type cladding layer, an active layer, a p-type semiconductor layer, and a protective layer on a substrate; an etching process of performing etching on one area of the n-type cladding layer, the active layer, the p-type semiconductor layer, and the protective layer, wherein the etching is performed from the protective layer to a part of the n-type cladding layer in a vertical direction; and a formation process of forming a first electrode on the protective layer and forming a second electrode on the n-type cladding layer exposed to the outside by the etching process.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and combine to generate light; a p-type cladding layer implemented with a semiconductor material different from the n-type cladding layer and deposited on the active layer to provide holes to the active layer; a protective layer implemented with a material of which light transmittance in a visible light wavelength band and electrical conductivity are respectively a preset first reference value and a preset second reference value or more, and deposited on the p-type cladding layer to protect the p-type cladding layer from the outside; and electrodes respectively formed on the n-type cladding layer and the protective layer.

According to one aspect of the present invention, provided is a method for manufacturing a light-emitting device, comprising: a deposition process of sequentially depositing an n-type cladding layer, an active layer, a p-type cladding layer, and a protective layer on a substrate; an etching process of performing etching on one area of the n-type cladding layer, the active layer, the p-type cladding layer, and the protective layer, wherein the etching is performed from the protective layer to a part of the n-type cladding layer in a vertical direction; and a formation process of forming a first electrode on the protective layer and forming a second electrode on the n-type cladding layer exposed to the outside by the etching process, wherein the p-type cladding layer is implemented with a semiconductor of a material different from the n-type cladding layer respectively.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer; a first electrode deposited on the p-type semiconductor layer to supply current to the p-type semiconductor layer and reflecting light generated in the active layer toward the n-type cladding layer; and a second electrode deposited on the n-type cladding layer to supply electrons to the n-type cladding layer and improving light extraction efficiency.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer; a first electrode deposited on the p-type semiconductor layer to supply current to the p-type semiconductor layer and reflecting light generated in the active layer toward the n-type cladding layer; and a second electrode deposited on the n-type cladding layer to supply electrons to the n-type cladding layer and improving light extraction efficiency, wherein the first electrode and the second electrode perform the role of an electrode and simultaneously include a metal electrode reflecting light incident thereon and a protective layer deposited on the metal electrode to protect the metal electrode from the external environment.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer; a first electrode deposited on the p-type semiconductor layer to supply current to the p-type semiconductor layer and reflecting light generated in the active layer toward the n-type cladding layer; and a second electrode deposited on the n-type cladding layer to supply electrons to the n-type cladding layer and improving light extraction efficiency, wherein the first electrode and the second electrode perform the role of an electrode and simultaneously include a metal electrode reflecting light incident thereon and a protective layer deposited on the metal electrode to protect the metal electrode from the external environment, and a metal electrode layer deposited between the p-type semiconductor layer or the n-type cladding layer and the metal electrode to improve the contact force of the metal electrode.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer; a first electrode deposited on the p-type semiconductor layer to supply current to the p-type semiconductor layer and reflecting light generated in the active layer toward the n-type cladding layer; a second electrode deposited on the n-type cladding layer to supply electrons to the n-type cladding layer and improving light extraction efficiency; and an insulation film laminated on the side surfaces of the n-type cladding layer, the active layer, and the p-type semiconductor layer and on the side surfaces and a part of the upper surface of the first electrode and the second electrode to protect each configuration from the outside.

According to one aspect of the present invention, in a method for manufacturing a light-emitting device, provided is a light-emitting device manufacturing method comprising: an etching process of performing etching to a position of the n-type cladding layer to form a mesa structure of a p-n junction using a wafer having a layer structure composed of an n-type cladding layer, an active layer, and a p-type semiconductor layer sequentially on a substrate; a deposition process for forming a first electrode on the upper surface of the mesa structure and a second electrode on the n-type cladding layer exposed by the etching process; and a lamination process of laminating an insulation film on the side surfaces of the n-type cladding layer, the active layer, and the p-type semiconductor layer and on the side surfaces and a part of the upper surface of the first electrode and the second electrode.

According to one aspect of the present invention, in a method for manufacturing a light-emitting device, unlike the above-described, the first electrode and the second electrode may be formed by different processes. That is, provided is a light-emitting device manufacturing method comprising: a first deposition process in which a first electrode is deposited on the upper surface of a p-type semiconductor layer in a specific area where a p-n junction mesa is to be formed sequentially on a substrate; an etching process of performing etching in a mesa structure form to a position of the n-type cladding layer, the active layer, the p-type semiconductor layer, and the first electrode; a second deposition process in which a second electrode is deposited on the n-type cladding layer exposed by the etching process; and a lamination process of laminating an insulation film on the side surfaces of the n-type cladding layer, the active layer, and the p-type semiconductor layer and on the side surfaces and a part of the upper surface of the first electrode and the second electrode.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer while hindering or blocking the supply of holes to some regions; a transparent electrode deposited on the p-type semiconductor layer to supply holes to the p-type semiconductor layer; a first electrode formed on the transparent electrode; and a second electrode deposited on the n-type cladding layer to supply electrons to the n-type cladding layer.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer while hindering or blocking the supply of holes to some regions; a transparent electrode deposited on the p-type semiconductor layer to supply holes to the p-type semiconductor layer; a first electrode formed on the transparent electrode; and a second electrode deposited on the n-type cladding layer to supply electrons to the n-type cladding layer, wherein the p-type semiconductor layer is deposited on the active layer as a semiconductor material doped with a p-type dopant and blocks the flow of current, or more specifically, holes and includes a p-type cladding layer including a current flow obstruction part and a p-type oxide layer implemented with a zinc oxide (ZnO) based compound and deposited on the p-type cladding layer.

According to one aspect of the present invention, provided is a light-emitting device comprising: a substrate; an n-type cladding layer deposited on the substrate and implemented with a semiconductor material doped with an n-type dopant; an active layer deposited on the n-type cladding layer, in which holes and electrons provided from the n-type cladding layer meet and recombine to generate light; a p-type semiconductor layer deposited on the active layer to provide holes to the active layer while hindering or blocking the supply of holes to some regions; a transparent electrode deposited on the p-type semiconductor layer to supply holes to the p-type semiconductor layer; a first electrode formed on the transparent electrode; and a second electrode deposited on the n-type cladding layer to supply electrons to the n-type cladding layer, wherein the p-type semiconductor layer is deposited on the active layer as a semiconductor material doped with a p-type dopant and includes a current flow obstruction part and a p-type cladding layer including a leakage current prevention part that blocks the occurrence of leakage current, and a p-type oxide layer implemented with a zinc oxide (ZnO) based compound and deposited on the p-type cladding layer.

According to one aspect of the present invention, in a method for manufacturing a light-emitting device, provided is a light-emitting device manufacturing method comprising: a first deposition process in which an n-type cladding layer, an active layer, and a p-type cladding layer are sequentially deposited on a substrate; a treatment process in which a plasma treatment using oxygen or a gas containing oxygen or an ion/electron injection (Implantation) process is performed on a preset area within the p-type cladding layer; a second deposition process in which a p-type oxide layer and a transparent electrode are deposited on the p-type cladding layer; an etching process in which etching is performed in a mesa structure form from the transparent electrode to a position of the n-type cladding layer; and a metal electrode formation process in which a first electrode is formed on the transparent electrode and a second electrode is formed on the n-type cladding layer exposed to the outside, respectively.

According to one aspect of the present invention, in a method for manufacturing a light-emitting device, provided is a light-emitting device manufacturing method comprising: a first deposition process in which an n-type cladding layer, an active layer, and a p-type cladding layer are sequentially deposited on a substrate; a first treatment process in which a plasma treatment using oxygen or a gas containing oxygen or an ion/electron injection (Implantation) process is performed on a preset area within the p-type cladding layer; a second deposition process in which a p-type oxide layer and a transparent electrode are deposited on the p-type cladding layer; an etching process in which etching is performed in a mesa structure form from the transparent electrode to a position of the n-type cladding layer; a second treatment process in which a plasma treatment is performed using oxygen or a gas containing oxygen; and a formation process in which a first electrode is formed on the transparent electrode and a second electrode is formed on the exposed n-type cladding layer, respectively.

As described above, according to one aspect of the present invention, there is an advantage that light efficiency can be improved by reducing the generation of internal pressure and improving the density of holes.

According to one aspect of the present invention, there is an advantage that light efficiency can be improved by having a hybrid type cladding layer implemented with semiconductor materials of different substances to reduce the generation of internal pressure and improve the density of holes.

According to one aspect of the present invention, there is an advantage that light efficiency can be improved by having a cladding layer of a heterogeneous material such as zinc oxide (ZnO) to reduce the generation of internal pressure and improve the density of holes.

According to one aspect of the present invention, there is an advantage that excellent light output can be obtained by including a reflective electrode having uniform current flow and excellent reflectivity.

Also, according to one aspect of the present invention, there is an advantage that light output can be improved by minimizing obstruction of output light due to an opaque metal electrode.

### BRIEF DESCRIPTION OF THE DRAWINGS

FIG. 1 is a view showing a configuration of a light-emitting device according to a first embodiment of the present invention.

FIG. 2 is a view showing a configuration of a p-type semiconductor layer according to the first embodiment of the present invention.

FIG. 3 is a graph showing internal quantum efficiency of a light-emitting device according to the first embodiment of the present invention and a conventional light-emitting device.

FIG. 4 is a view comparing internal characteristics of an active layer of a light-emitting device according to the first embodiment of the present invention and a conventional light-emitting device.

FIGS. 5 to 10 are views showing a manufacturing process of a light-emitting device according to the first embodiment of the present invention.

FIG. 11 is a view showing a configuration of a light-emitting device according to a second embodiment of the present invention.

FIGS. 12 and 13 are views showing a configuration and energy band characteristics of an active layer according to the second embodiment of the present invention.

FIG. 14 is a view showing a configuration of a p-type cladding layer according to the second embodiment of the present invention.

FIGS. 15 to 17 are views showing a manufacturing process of a light-emitting device according to the second embodiment of the present invention.

FIG. 18 is a view showing a change in light emission intensity according to an applied current of a light-emitting device according to the second embodiment of the present invention.

FIG. 19 is a view showing a configuration of a light-emitting device according to a third embodiment of the present invention.

FIGS. 20A and 20B are views showing a configuration of an electrode layer according to the third embodiment of the present invention.

FIG. 21 is a graph showing voltage and current characteristics of electrodes implemented with different components.

FIGS. 22A and 22B are graphs showing voltage and current characteristics of an Al or Al/Ag-based ohmic electrode.

FIGS. 23 and 24 are views showing a structure of an electrode according to the third embodiment of the present invention.

FIGS. 25 and 26 are views showing a manufacturing process of a light-emitting device according to the third embodiment of the present invention.

FIG. 27 is a view showing a configuration of a light-emitting device according to a fourth embodiment of the present invention.

FIG. 28 is a view showing a configuration of a p-type semiconductor layer according to a fourth or fifth embodiment of the present invention.

FIG. 29 is a plan view of a p-type semiconductor layer according to the fourth or fifth embodiment of the present invention.

FIG. 30 is a view comparing light efficiency of a light-emitting device according to the fourth embodiment of the present invention and a conventional light-emitting device.

FIGS. 31 to 37 are views showing a manufacturing process of a light-emitting device according to an embodiment of the present invention.

FIG. 38 is a view showing a configuration of a light-emitting device according to a fifth embodiment of the present invention.

### DETAILED DESCRIPTION

The present disclosure may be changed in various ways and may have various embodiments. Specific embodiments are to be illustrated in the drawings and specifically described. It should be understood that the present disclosure is not intended to be limited to the specific embodiments, but includes all of changes, equivalents and/or substitutions included in the spirit and technical range of the present disclosure. Similar reference numerals are used for similar components while each drawing is described.

Terms, such as a first, a second, A, and B, may be used to describe various components, but the components should not be restricted by the terms. The terms are used to only distinguish one component from another component. For example, a first component may be referred to as a second component without departing from the scope of rights of the present disclosure. Likewise, a second component may be referred to as a first component. The term “and/or” includes a combination of a plurality of related and described items or any one of a plurality of related and described items.

When it is described that one component is “connected” or “coupled” to the other component, it should be understood that one component may be directly connected or coupled to the other component, but a third component may exist between the two components. In contrast, when it is described that one component is “directly connected to” or “directly coupled to” the other component, it should be understood that a third component does not exist between the two components.

Terms used in this application are used to only describe specific embodiments and are not intended to restrict the present disclosure. An expression of the singular number includes an expression of the plural number unless clearly defined otherwise in the context. In this specification, a term, such as “include” or “have”, is intended to designate the presence of a characteristic, a number, a step, an operation, a component, a part or a combination of them, and should be understood that it does not exclude the existence or possible addition of one or more other characteristics, numbers, steps, operations, components, parts, or combinations of them in advance.

All terms used herein, including technical terms or scientific terms, have the same meanings as those commonly understood by a person having ordinary knowledge in the art to which the present disclosure pertains, unless defined otherwise in the specification.

Terms, such as those defined in commonly used dictionaries, should be construed as having the same meanings as those in the context of a related technology, and are not construed as ideal or excessively formal meanings unless explicitly defined otherwise in the application.

Furthermore, each construction, process, procedure, or method included in each embodiment of the present disclosure may be shared within a range in which the constructions, processes, procedures, or methods do not contradict each other technically.

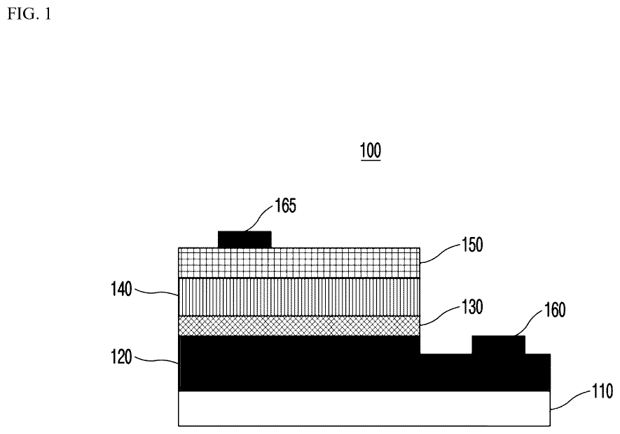

FIG. 1 is a diagram illustrating the configuration of a light-emitting device according to an embodiment of the present invention.

Referring to FIG. 1, a light-emitting device (100) according to an embodiment of the present invention includes a substrate (110), an n-type cladding layer (120), an active layer (130), a p-type semiconductor layer (140), a protective layer (150), and electrodes (160, 165).

The substrate (110) grows an n-type cladding layer (120) on its upper surface. The substrate (110) may be implemented as sapphire; however, it is not limited thereto and may be replaced with any material capable of supporting gallium nitride (GaN) growth.

The n-type cladding layer (120) is deposited on the substrate (110) and is implemented with a semiconductor material doped with n-type dopants to provide electrons to the active layer (130). The n-type cladding layer (120) may be deposited on the substrate (110) by epitaxial single-crystal deposition. The n-type cladding layer (120) may be implemented as n-type gallium nitride (n-GaN), but is not limited thereto and may be replaced with n-type InGaN, n-type AlGaN, n-type AlInGaN, or combinations thereof.

The active layer (130) is deposited on the n-type cladding layer (120). In the active layer (130), electrons supplied from the n-type cladding layer (120) and holes supplied from the p-type semiconductor layer (140) recombine to generate light. The active layer (130) comprises a well layer having a relatively small energy bandgap and a barrier layer having a relatively large bandgap. The active layer (130) may be implemented using InGaN layers of different indium concentrations, InGaN/GaN, or GaN/AlGaN multilayers, or combinations thereof.

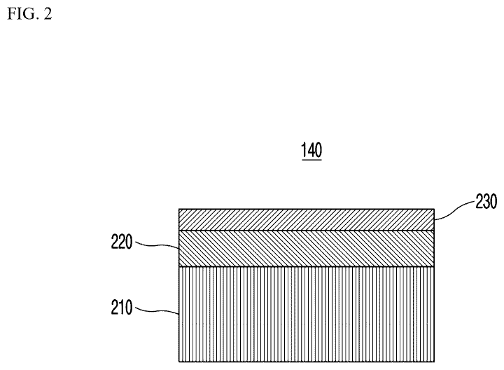

The p-type semiconductor layer (140) is deposited on the active layer (130) and supplies holes to the active layer (130). As illustrated in FIG. 2, the p-type semiconductor layer (140) is configured to minimize internal strain and enhance the hole transport rate toward the active layer (130).

FIG. 2 illustrates the configuration of the p-type semiconductor layer according to an embodiment of the present invention, and FIG. 4 shows a comparison of internal characteristics of the active layer between the inventive light-emitting device and a conventional one.

Referring to FIG. 2, the p-type semiconductor layer (140) according to an embodiment includes a p-type cladding layer (210), an internal-strain relaxation layer (220), and a hole transport enhancement layer (230).

The p-type cladding layer (210) is deposited immediately on the active layer (130) and provides holes transmitted therein to the active layer (130). The p-type cladding layer (210) may be deposited via epitaxial single-crystal growth. It may be implemented as p-type GaN as in the conventional case, but may alternatively be implemented as p-type InGaN, p-type AlGaN, p-type AlInGaN, or combinations thereof.

The internal-strain relaxation layer (220) is deposited on the p-type cladding layer (210) with a predetermined thickness to minimize internal stress that may occur between the active layer (130) and the p-type cladding layer (210). The layer may be deposited by chemical vapor deposition (CVD), molecular beam epitaxy (MBE), pulsed laser deposition (PLD), or hybrid beam deposition (HBD). Preferably, for zinc oxide-based materials, the HBD method is suitable.

The internal-strain relaxation layer (220) is made of a zinc oxide (ZnO)-based compound having a hexagonal crystal structure and may include group II and group VI elements such as ZnO, BeZnO, MgZnO, BeMgZnO, ZnSO, ZnSeO, ZnSSeO, ZnCdO, or ZnCdSeO. It has similar electrical and optical characteristics to those of the p-type cladding layer (210) but a larger lattice constant and higher hole concentration. Accordingly, the internal-strain relaxation layer (220) can reduce internal pressure between the active layer (130) and the p-type cladding layer (210).

When the internal pressure between the active layer (130) and the p-type cladding layer (210) is reduced, as shown in FIG. 4, the device exhibits a smaller flat-band voltage and piezoelectric voltage, resulting in a broader depletion region and improved hole injection efficiency, thereby enhancing the internal quantum efficiency.

The internal-strain relaxation layer (220) may have a thickness of 10 to 1000 nm, preferably 50 to 200 nm, and may be doped with p-type impurities or formed with zinc vacancies to increase hole concentration. The p-type dopant may include one or more acceptor impurities such as H, Li, Na, K, Rb, Cs, Fr, Cu, Ag, N, P, As, Sb, or Bi at concentrations between 1×10¹⁷ and 1×10²⁰ atoms/cm³ , preferably 5×10¹⁸ to 5×10¹⁹ atoms/cm³ .

Alternatively, the internal-strain relaxation layer (220) may be undoped but thermally treated in an oxygen-containing atmosphere at 400-700° C. (preferably 450-550° C.) for 1-600 minutes (preferably 10-60 minutes), causing zinc deficiency and increasing hole concentration.

The hole transport enhancement layer (230) is deposited on the internal-strain relaxation layer (220) with a predetermined thickness to form ohmic contact with the protective layer (150). The layer is also made of a ZnO-based compound and may be doped with p-type, n-type, or both types of impurities to improve current conduction without photon absorption. Its thickness may be 1-10 nm, preferably below 50 nm, with impurity concentrations above 1×10¹⁹ atoms/cm³ (preferably 5×10¹⁹-1×10²¹ atoms/cm³ ). Suitable dopants include acceptor impurities (N, P, As, Sb, etc.) and donor impurities (Al, Ga, In, etc.).

The p-type semiconductor layer (140) having the above configuration minimizes internal strain between the active layer (130) and the p-type cladding layer (210), enhances hole injection, and ensures good ohmic contact with the protective layer (150). Thus, it removes accumulated electrons in the active layer, eliminates piezoelectric fields, and improves luminous efficiency.

Impurities at a predetermined concentration are doped into the hole transport enhancement layer (230). Here, the predetermined concentration may be a concentration sufficient to change the energy bandgap so that ohmic contact is formed between the internal-strain relaxation layer (220) and the protective layer (150), and may be 1*10¹⁹ atoms/cm⁻³ or more, and more specifically 5*10¹⁹ to 1*10²¹ atoms/cm⁻³. The impurities doped into the hole transport enhancement layer (230) may be acceptor impurities, and may include one or more of H, Li, Na, K, Rb, Cs, Fr, Cu, Ag, N, P, As, Sb, and Bi. More preferably, the acceptor impurity may be N, P, or As, and even more preferably N or As. Meanwhile, the impurities doped into the hole transport enhancement layer (230) may be donor impurities, and may include one or more of B, Al, Ga, In, Ti, F, Cl, Br, and I. More preferably, the donor impurity may be Al, Ga, or In. Alternatively, the impurities doped into the hole transport enhancement layer (230) may include at least one acceptor impurity and at least one donor impurity. Such impurities are doped into the hole transport enhancement layer (230) at the predetermined concentration or higher.

In doping the above-described impurities into the hole transport enhancement layer (230) to the predetermined concentration, the layer may be formed by performing plasma surface treatment on the surface of the internal-strain relaxation layer (220) or by an ion implantation process. By the ion implantation process, the above-described impurities at the predetermined concentration may be implanted and doped into the hole transport enhancement layer (230) to a predetermined thickness.

Alternatively, the hole transport enhancement layer (230) may be formed after the internal-strain relaxation layer (220) is deposited on the p-type cladding layer (210), by performing a high-temperature heat-treatment process in a gas atmosphere containing the above-described impurity molecules, or by performing a rapid thermal annealing process at 300 to 1000° C.

Alternatively, the hole transport enhancement layer (230) may be formed after the internal-strain relaxation layer (220) is deposited on the p-type cladding layer (210), by surface-treating the internal-strain relaxation layer (220) with an acid or base solution containing the above-described impurity molecules.

By including the above-described configuration (210 to 230), the p-type semiconductor layer (140) can minimize internal strain that may occur between the active layer (130) and the p-type cladding layer (210), allow more holes to be delivered into the active layer, and form ohmic contact between itself and the protective layer (150) so that the protective layer (150) can be smoothly deposited. In particular, since the p-type semiconductor layer (140) can inject a relatively larger amount of holes into the active layer (130) than in the conventional case, it can remove electrons accumulated in the active layer (130) due to excessive electron supply into the active layer (130). Accordingly, the p-type semiconductor layer (140) can remove a piezoelectric field formed in the active layer (130) due to accumulated electrons, thereby improving luminous efficiency.

The protective layer (150) is deposited on the p-type semiconductor layer (140) to protect the p-type semiconductor layer (140) from the outside. The p-type semiconductor layer (140), in particular, the internal-strain relaxation layer (220) and the hole transport enhancement layer (230) within the p-type semiconductor layer (140), are implemented with the above-described components and react with most acidic and basic chemicals. Accordingly, the protective layer (150) is deposited on the p-type semiconductor layer (140) to protect the p-type semiconductor layer (140) from the outside. Meanwhile, since the protective layer (150) is deposited on the p-type semiconductor layer (140), it must not obstruct propagation of light generated in the active layer (130), and must diffuse the current injected from the electrode (165) so that holes can be uniformly delivered into the active layer (130) over the entire region of the p-type semiconductor layer (140). Accordingly, the protective layer (150) is implemented with a material having (i) a transmittance in the visible wavelength band of at least a predetermined first reference value and (ii) an electrical conductivity of at least a predetermined second reference value. For example, the protective layer (150) may be implemented as ITO, NiO, GaZnO, InZnO, InGaZnO, or graphene (Graphene). The protective layer (150) is implemented with the above-described components and is deposited on the p-type semiconductor layer (140) by physical vapor deposition (PVD), including E-beam deposition or sputtering, or by chemical vapor deposition (CVD). The protective layer (150) may be deposited to have a predetermined thickness, for example, within a thickness range of 10 to 1000 nm.

As the protective layer (150) is implemented as described above, it is possible to uniformly inject holes from the p-type semiconductor layer (140) into the active layer (130) while protecting the p-type semiconductor layer (140) from the outside.

The electrodes (160, 165) are formed on the n-type cladding layer (120) and the protective layer (150), respectively, to supply current to the respective components (120, 150). The electrode (160) is formed on the n-type cladding layer (120) exposed to the outside by etching, and the electrode (165) is formed on the protective layer (150). The electrodes (160, 165) may be implemented with one or more metals selected from Al, Ag, Cr, Cu, Mo, Ni, Pd, Ti, and W, or alloys thereof. In particular, since the electrode (165) is located in the direction in which light is emitted from the active layer (130), the electrode (165) may be implemented with Al or Ag having excellent reflectance.

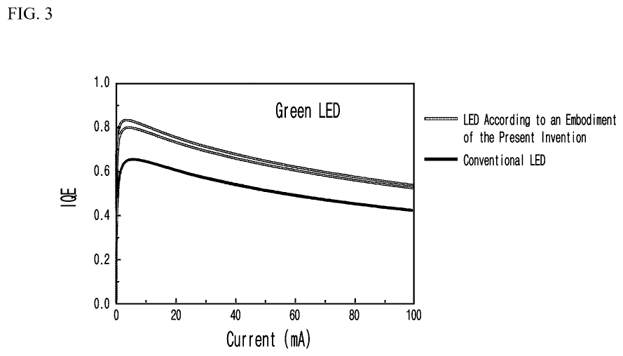

As the light-emitting device (100) includes the above-described configuration, it can be confirmed that it has excellent quantum efficiency (light efficiency) as shown in FIG. 3.

FIG. 3 is a graph showing internal quantum efficiency of the light-emitting device according to an embodiment of the present invention and that of a conventional light-emitting device.

Referring to FIG. 3, it can be confirmed that the light-emitting device (100) has an internal quantum efficiency improved by 30% or more compared to the conventional one.

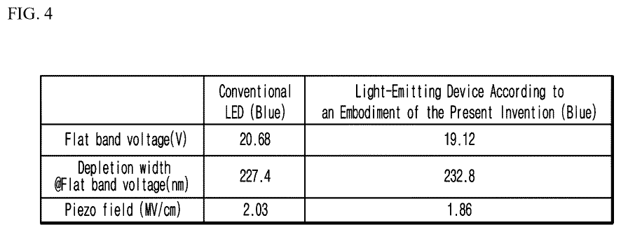

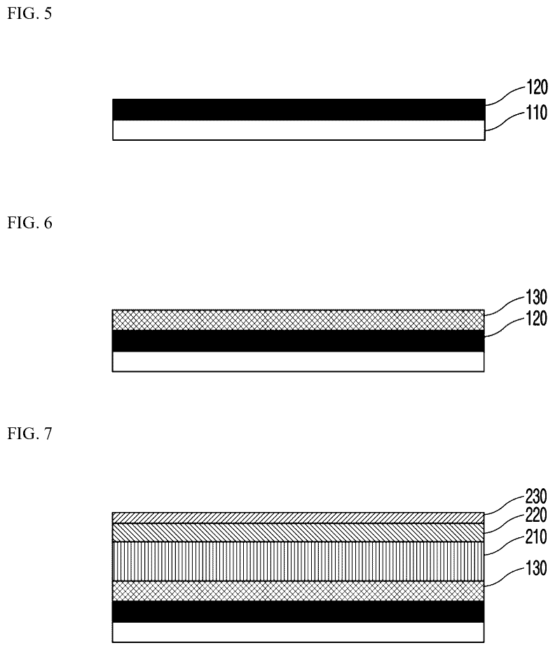

FIGS. 5 to 10 are diagrams illustrating a manufacturing process of the light-emitting device according to an embodiment of the present invention. Manufacturing of the light-emitting device (100) may be performed by a light-emitting-device manufacturing apparatus.

Referring to FIGS. 5 to 8, the n-type cladding layer (120), the active layer (130), the p-type semiconductor layer (140), and the protective layer (150) are sequentially deposited on the substrate (110).

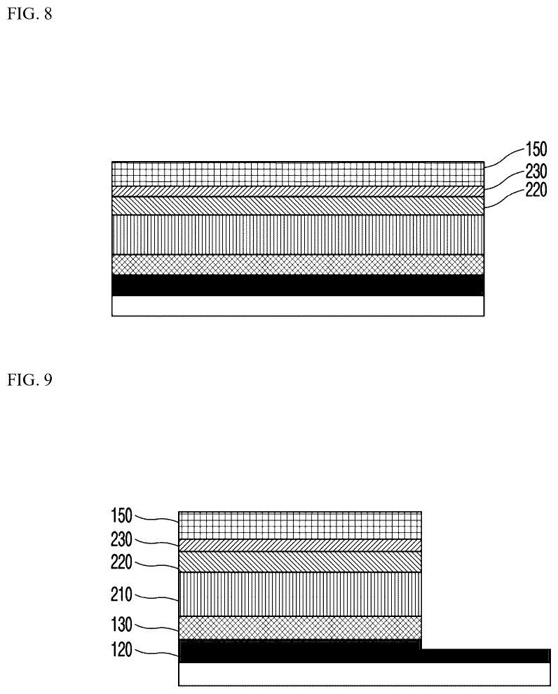

Referring to FIG. 9, etching is performed on one surface region of the active layer (130), the p-type semiconductor layer (140), the protective layer (150), and the n-type cladding layer (120). The etching proceeds from the protective layer (150) in a vertical direction to a portion of the n-type cladding layer (120).

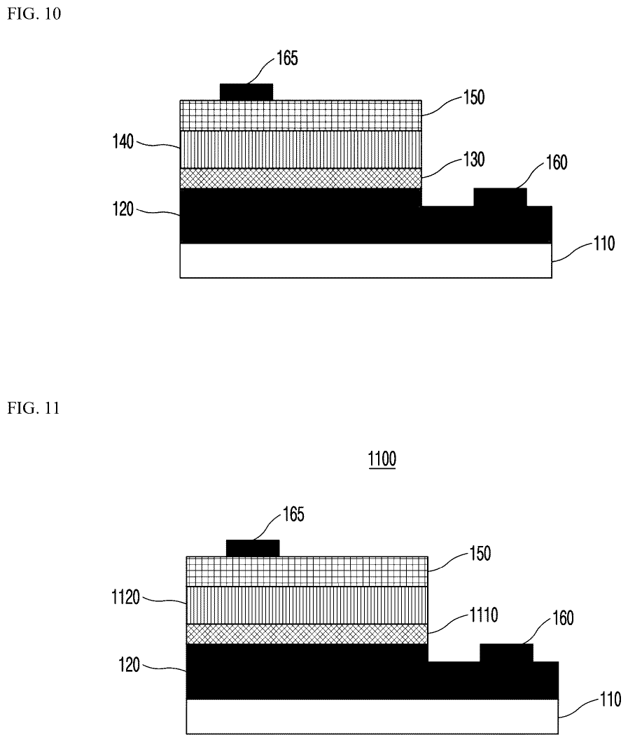

Referring to FIG. 10, as etching is performed, the electrode (160) is formed on the n-type cladding layer (120) exposed to the outside, and the electrode (165) is formed on the protective layer (150).

FIG. 11 is a diagram illustrating a configuration of a light-emitting device according to a second embodiment of the present invention.

Referring to FIG. 11, the light-emitting device (1100) according to the second embodiment of the present invention includes the substrate (110), the n-type cladding layer (120), an active layer (1110), a p-type cladding layer (1120), the protective layer (150), and the electrodes (160, 165). Since the substrate (110), the n-type cladding layer (120), the protective layer (150), and the electrodes (160, 165) are the same as those in the light-emitting device (100), repeated descriptions thereof will be omitted.

The active layer (1110) is deposited on the n-type cladding layer (120), similarly to the active layer (130), and generates light by combining electrons supplied from the n-type cladding layer (120) and holes supplied from the p-type cladding layer (140). The active layer (1110) is implemented with a well layer (Quantum Well) having a relatively small energy bandgap and a barrier layer (Quantum Barrier) having a relatively large energy bandgap. The active layer (1110) may be implemented as InGaN layers having different In concentrations, InGaN/GaN layers, or GaN/AlGaN layers, or combinations thereof.

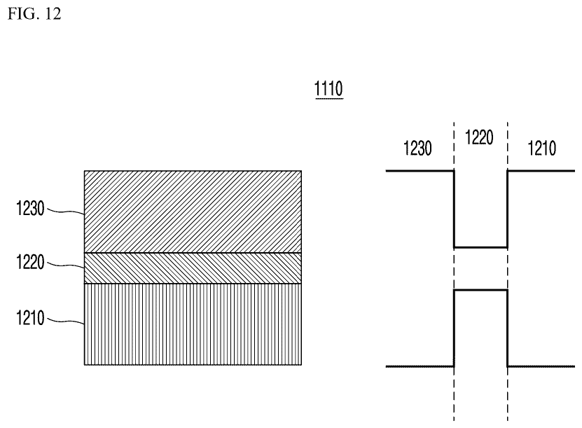

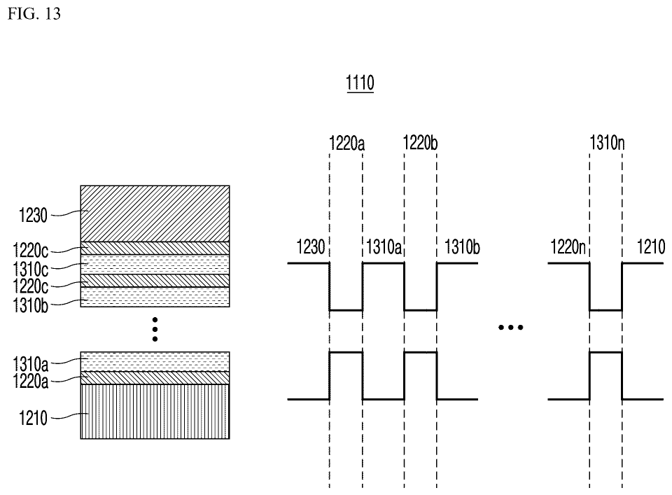

In particular, the active layer (1110) includes barrier layers at outermost portions of the active layer (1110). The outermost barrier layers are implemented to have at least a predetermined thickness in order to block oxygen from entering into the active layer (1110). However, in order to secure densities and mobilities of electrons and holes, the outermost barrier layer close to the n-type cladding layer (120) may be doped with an n-type dopant, and the outermost barrier layer close to the p-type cladding layer (140) may be doped with a p-type dopant. With such implementation, the active layer (1110) can prevent inflow of oxygen into its interior. The active layer (1110) can prevent inflow of oxygen even without additionally including a separate layer (for example, a protective layer) outside the active layer (1110) to prevent oxygen inflow. A specific structure of the active layer (1110) is shown in FIGS. 12 and 13.

FIGS. 12 and 13 are diagrams illustrating a configuration of the active layer and energy-band characteristics according to the second embodiment of the present invention.

As can be seen in FIG. 12, the well layer (1220) is implemented to have a relatively small energy bandgap, and the barrier layers (1210, 1230) are implemented to have relatively large energy bandgaps.

At this time, as described above, the outermost barrier layer (1210) close to the n-type cladding layer (hereinafter referred to as a first barrier layer) and the outermost barrier layer (1230) close to the p-type cladding layer (hereinafter referred to as a second barrier layer) are implemented to have at least a predetermined thickness. Further, to secure electron density and mobility, the first barrier layer (1210) is implemented as GaN, InGaN, or AlGaN doped with an n-type impurity such as Si or Ge at a concentration of 1*10¹⁶ to 1*10²⁰ cm⁻³, and to secure hole density and mobility, the second barrier layer (1230) is implemented as GaN, InGaN, or AlGaN doped with a p-type impurity such as Mg at a concentration of 1*10¹⁶ to 1*10²⁰ cm⁻³.

Alternatively, as shown in FIG. 13, a plurality of well layers (1220a to 1220n) and a plurality of barrier layers (1310a to 1310n) are deposited between the first barrier layer (1210) and the second barrier layer (1230), and the active layer (1110) may be implemented as a multiple quantum well.

Since the active layer (1110) has such a structure, it is not necessary to include an EBL (Electron Blocking Layer), which conventional GaN-based light-emitting devices include between the active layer and the p-type cladding layer to control the flow of electrons.

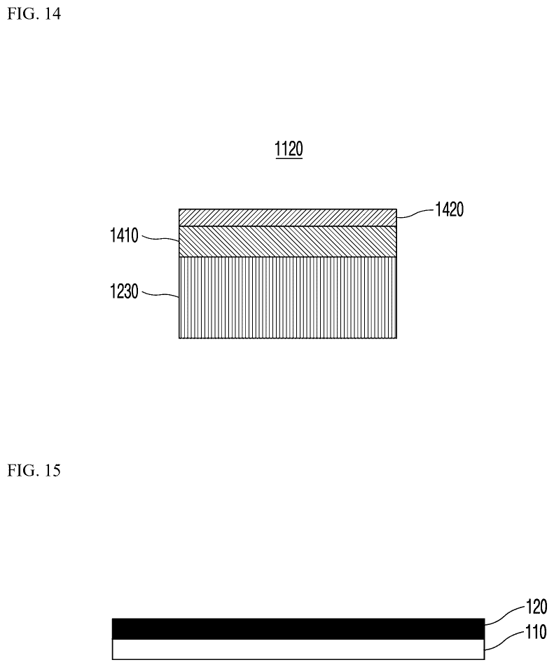

Referring again to FIG. 11, the p-type cladding layer (1120) is deposited on the active layer (1110), particularly on the second barrier layer (1230), and supplies holes to the active layer (1110). At this time, as the p-type cladding layer (1120) is implemented in the structure shown in FIG. 14, internal strain can be minimized and the hole transport rate into the active layer (1110) can also be improved.

FIG. 14 is a diagram illustrating a configuration of the p-type cladding layer according to the second embodiment of the present invention.

Referring to FIG. 14, the p-type cladding layer (1120) according to the second embodiment of the present invention includes an internal-strain relaxation layer (1410) and a hole transport enhancement layer (1420).

The internal-strain relaxation layer (1410) has the same characteristics as the internal-strain relaxation layer (220) except that it is deposited immediately on the second barrier layer (1230).

The hole transport enhancement layer (1420) also has the same characteristics as the hole transport enhancement layer (230).

By including the above-described configuration (1410 and 1420), the p-type cladding layer (1120) can minimize internal strain that may occur between itself and the active layer (1110), remarkably improve hole transport efficiency, and form ohmic contact between itself and the protective layer (150) so that the protective layer (150) can be deposited.

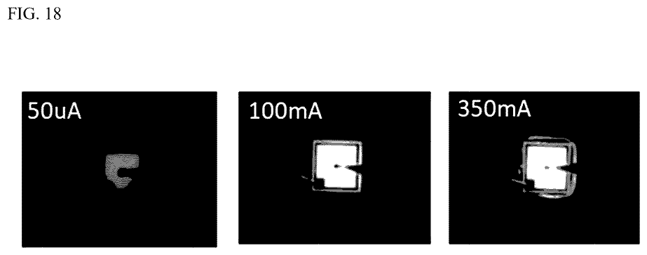

As the light-emitting device (1100) includes the above-described configuration, it can be confirmed that it has light-emission intensity characteristics as shown in FIG. 18.

FIG. 18 is a diagram illustrating a change in light-emission intensity of the light-emitting device according to the second embodiment of the present invention depending on an applied current.

Referring to FIG. 18, it can be confirmed that the light-emitting device (1100) outputs light in a blue wavelength band, and that the light-emission intensity increases as the amount of injected current increases.

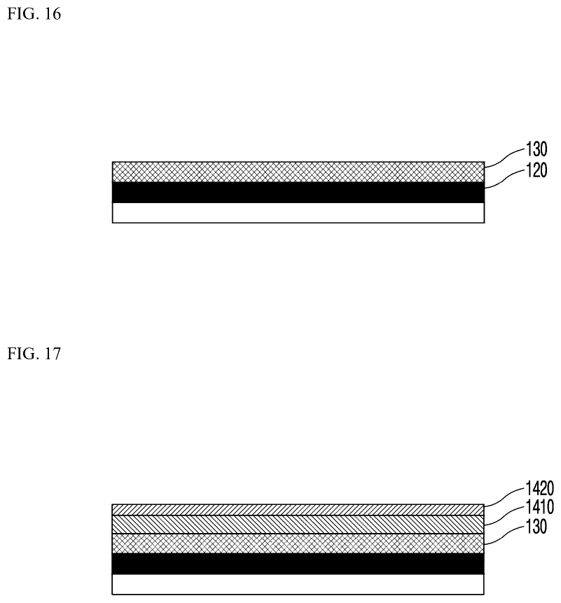

FIGS. 15 to 17 are diagrams illustrating a manufacturing process of the light-emitting device according to the second embodiment of the present invention.

Referring to FIGS. 15 to 17, the n-type cladding layer (120), the active layer (130), the p-type semiconductor layer (140), and the protective layer (150) are sequentially deposited on the substrate (110). More specifically, the internal-strain relaxation layer (1410) and the hole transport enhancement layer (1420) are deposited on the active layer (130).

Thereafter, the light-emitting device is manufactured according to the same process as described above with reference to FIGS. 9 and 10.

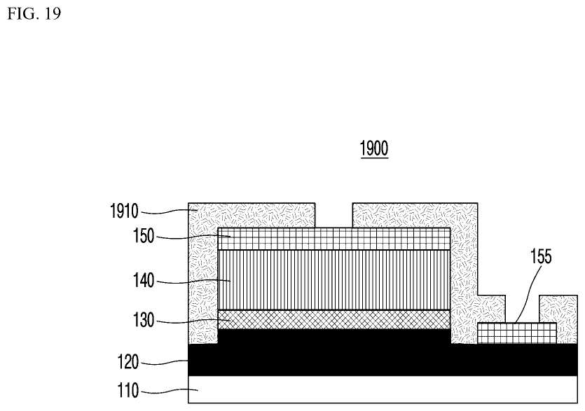

FIG. 19 is a diagram illustrating a configuration of a light-emitting device according to a third embodiment of the present invention.

Referring to FIG. 19, the light-emitting device (1900) according to an embodiment of the present invention includes the substrate (110), the n-type cladding layer (120), the active layer (130), the p-type semiconductor layer (140), electrodes (150, 155), and an insulating film (1910). Since the substrate (110), the n-type cladding layer (120), the active layer (130), and the electrodes (150, 155) in the light-emitting device (1900) are the same as those in the light-emitting device (100), repeated descriptions thereof will be omitted. Meanwhile, the p-type semiconductor layer (140) in the light-emitting device (1900) is implemented with the same configuration as that in the light-emitting device (100), except that the hole transport enhancement layer (230) is doped with impurities at a predetermined concentration for the purpose of forming ohmic contact between the internal-strain relaxation layer (220) and the electrode (150).

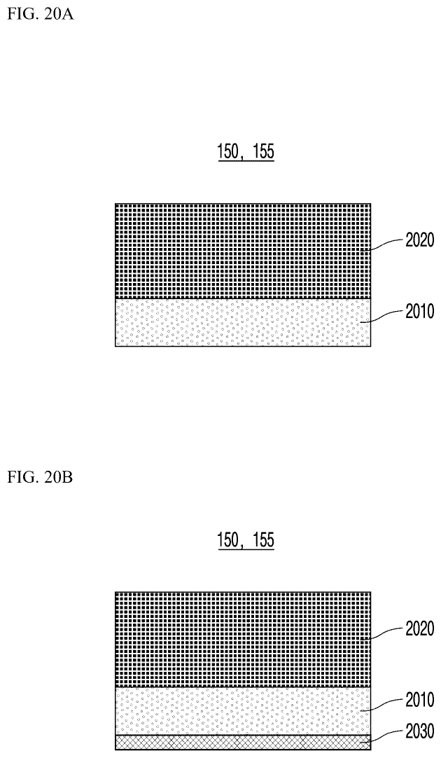

The electrode (150) is deposited on the p-type semiconductor layer (140), more specifically on the hole transport enhancement layer (230), to supply current to the p-type semiconductor layer (140). The electrode (150) is implemented with a metal having excellent reflectance, thereby reflecting light generated in the active layer (130) toward the n-type cladding layer (120). The electrode (150) may be formed by deposition using, for example, an EB (electron-beam) method, an evaporation method, or a sputtering method. The electrode (150) performs the above-described operation while having the configuration shown in FIG. 20A or FIG. 20B.

FIGS. 20A and 20B are diagrams illustrating a configuration of an electrode layer according to a third embodiment of the present invention.

Referring to FIG. 20A, an electrode layer (150, and the same applies to 155 to be described later) according to an embodiment of the present invention includes a metal electrode (2010) and a protective layer (2020).

The metal electrode (2010) functions as an electrode while reflecting light incident thereon. The metal electrode (2010) is deposited on the hole transport enhancement layer (230) to reflect light incident toward the metal electrode (2010). The metal electrode (2010) may be implemented as aluminum (Al), or may include aluminum (Al) and silver (Ag). When implemented as aluminum, the metal electrode (2010) may have a thickness of 20 to 10,000 nm. When including aluminum and silver, the metal electrode (2010) may be implemented in a form in which aluminum having a thickness of less than 10 nm is first deposited and silver is then deposited on the aluminum to a thickness of 200 to 1,000 nm.

The protective layer (2020) is deposited on the metal electrode (2010) to protect the metal electrode (2010) from an external environment. As described above, the metal electrode (2010) is implemented as aluminum or silver, which are metals having excellent reflectance; however, the metal used to implement the metal electrode (2010) is prone to oxidation and tends to readily undergo chemical reactions with water or other chemicals. Accordingly, the protective layer (2020) is deposited on the metal electrode (2010) to minimize exposure of the metal electrode (2010) to the external environment. The protective layer (2020) may be implemented as aluminum (Al), titanium (Ti), chromium (Cr), nickel (Ni), copper (Cu), palladium (Pd), molybdenum (Mo), tantalum (Ta), tungsten (W), rhenium (Re), platinum (Pt), or gold (Au), or as an alloy of the foregoing components.

As the electrode layer (150) has the above structure, it can transfer current to the p-type semiconductor layer (140), reflect light incident thereto, and simultaneously exhibit high stability.

Meanwhile, the electrode layer (150) according to an embodiment of the present invention may be implemented as shown in FIG. 20B.

Referring to FIG. 20B, the electrode layer (150, and the same applies to 155 to be described later) according to an embodiment of the present invention may further include a metal contact layer (2030) in addition to the metal electrode (2010) and the protective layer (2020).

Even when the metal electrode (2010) is deposited on the hole transport enhancement layer (230), there is a concern that adhesion may be relatively weak and peeling may occur. Accordingly, in order to improve adhesion of the metal electrode (2010) on the hole transport enhancement layer (230), the metal contact layer (2030) may be first deposited between the two layers (230, 2010). The metal contact layer (2030) may be implemented as aluminum (Al) and deposited as a thin film having a thickness of less than 10 nm. Alternatively, in order to further improve adhesion, an additional metal layer implemented as chromium (Cr), titanium (Ti), palladium (Pd), or molybdenum (Mo) may be first deposited on the hole transport enhancement layer (230) to a thickness of less than 2 nm, and an aluminum (Al) layer having a thickness of less than 10 nm may be deposited on the additional metal layer. The metal electrode (2010) and the protective layer (2020) may be deposited on the metal contact layer (2030), thereby further improving adhesion of the metal electrode (2010) and the protective layer (2020).

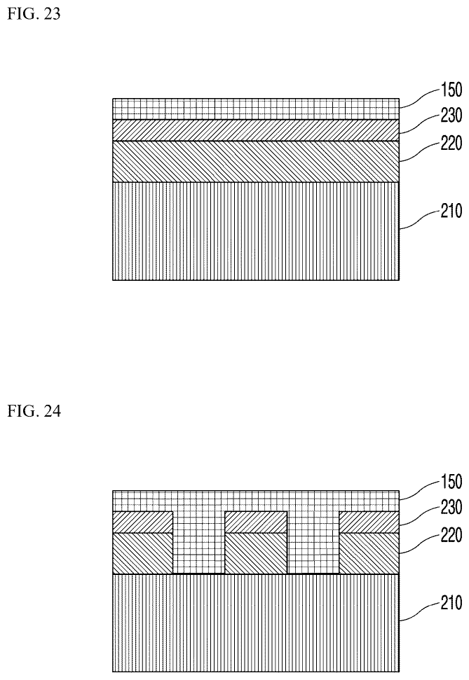

Referring again to FIG. 19, the electrode (150) may have the above-described structure and perform the above-described operation. In this case, when the electrode (150) is deposited on the p-type semiconductor layer (140), the electrode (150) may have the structure shown in FIG. 23 or FIG. 24.

FIGS. 23 and 24 are diagrams illustrating structures of an electrode according to the third embodiment of the present invention.

Referring to FIG. 23, the electrode (150) according to an embodiment of the present invention may have a structure uniformly deposited on the p-type semiconductor layer (140), more specifically on the hole transport enhancement layer (230).

Meanwhile, referring to FIG. 24, before the electrode (150) is deposited, etching may be performed on portions of the internal-strain relaxation layer (220) and the hole transport enhancement layer (230), or at predetermined intervals thereof, so that a portion of the p-type cladding layer (210) is exposed. In a state in which etching has been performed on the internal-strain relaxation layer (220) and the hole transport enhancement layer (230), deposition of the electrode (150) may be performed. Accordingly, the electrode (150) can directly contact a portion of the p-type cladding layer (210), thereby delivering current more efficiently to the p-type cladding layer (210) directly without passing through the internal-strain relaxation layer (220) and the hole transport enhancement layer (230).

Referring again to FIG. 19, the electrode (155) is deposited on the n-type cladding layer (120) to supply electrons to the n-type cladding layer (120). The electrode (155) may also be formed by deposition using, for example, an EB method, an evaporation method, or a sputtering method. Likewise, the electrode (155) may be implemented with a metal having excellent reflectance, similarly to the electrode (150), thereby improving light-extraction efficiency. Structurally, light generated in the active layer (130) does not directly reach the electrode (155). However, due to a refractive-index difference between the light-emitting device (100) and air, light generated in the active layer (130) tends to be trapped inside the light-emitting device. Accordingly, a large amount of light generated and emitted from the active layer (130) may also be incident on the electrode (155). By implementing the electrode (155) with a highly reflective metal, the electrode (155) reflects the light without absorbing it, thereby improving light output characteristics of the light-emitting device (100).

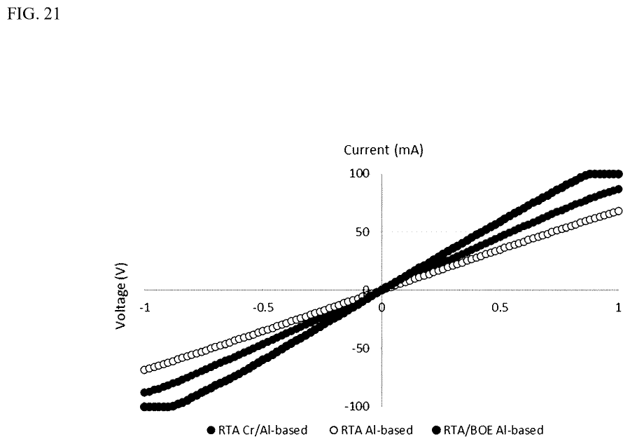

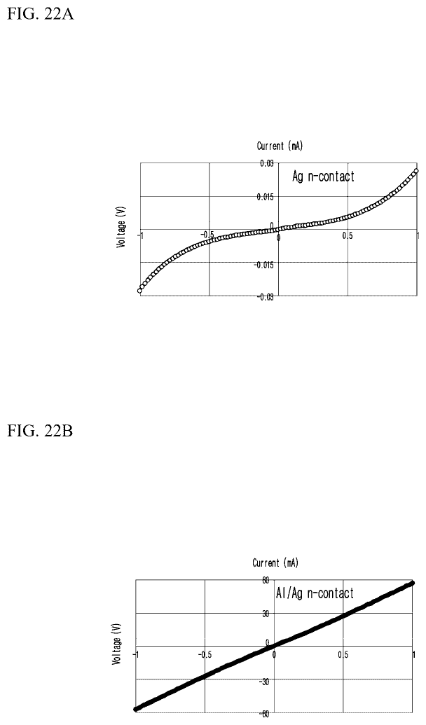

As shown in FIG. 20A, the electrode (155) may include the reflective electrode (2010) and the protective layer (2020) described above, or, as shown in FIG. 20B, the electrode (155) may further include the metal contact layer (2030) in addition to the metal electrode (2010) and the protective layer (2020). Accordingly, the electrode (155) has electrical characteristics shown in FIG. 21 or FIG. 22A or 22B.

FIG. 21 is a graph showing voltage and current characteristics of electrodes implemented with different components, and FIGS. 22A and 22B are graphs showing voltage and current characteristics of Al-or Al/Ag-based ohmic electrodes.

Referring to FIG. 21, it can be confirmed that even when a metal electrode (2010) including aluminum (Al) or including aluminum (Al) and silver (Ag) is first deposited on the n-type cladding layer (120), good ohmic contact is formed. However, when the metal contact layer (2030) implemented with chromium (Cr) or the like is first deposited and then the metal electrode (2010) is deposited, more stable adhesion and good ohmic contact can be achieved.

Meanwhile, referring to FIGS. 22A and 22B, silver (Ag) has the highest reflectance among metals, but when deposited on the n-type cladding layer (120), ohmic contact is not formed, which may cause difficulty in using silver as an n-type metal electrode (2010). However, as described above, when the metal electrode (2010) is implemented to include silver together with aluminum, good ohmic contact can be formed. Further, to form even better ohmic contact, the metal contact layer (2030) may be additionally deposited between the two layers (230, 2010). Accordingly, the electrodes (150, 155) can form excellent ohmic contact with the p-type semiconductor layer (140).

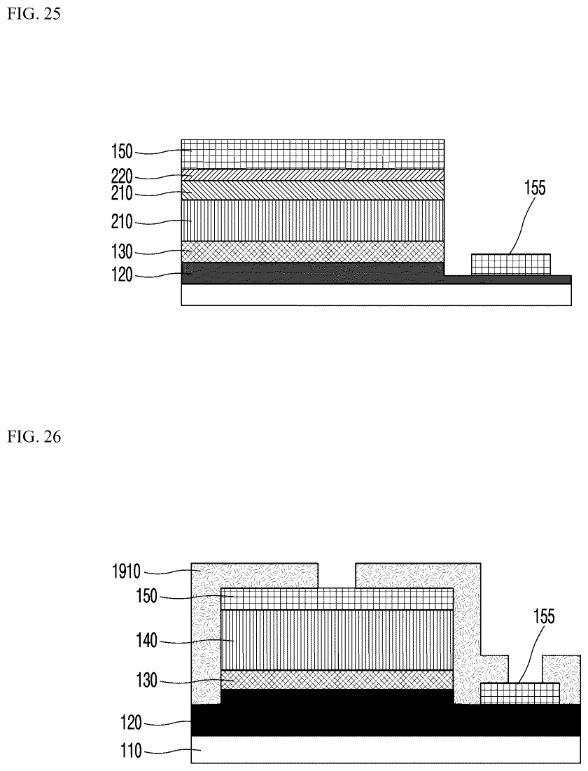

FIGS. 25 and 26 are diagrams illustrating a manufacturing process of a light-emitting device according to the third embodiment of the present invention.

The manufacturing process shown in FIGS. 5 to 9 is performed.

Referring to FIG. 25, as etching is performed, the electrode (155) is deposited on the n-type cladding layer (120) exposed to the outside.

Referring again to FIG. 19, an insulating film (1910) is stacked up to side surfaces of the n-type cladding layer (120), the active layer (130), and the p-type semiconductor layer (140), and up to side surfaces and a portion of a top surface of the electrodes (150, 155), thereby protecting each component in the light-emitting device (100) from the outside and electrically isolating an n-type region and a p-type region.

Referring to FIG. 26, the insulating film (1910) is stacked up to side surfaces of the n-type cladding layer (120), the active layer (130), and the p-type semiconductor layer (140), and up to side surfaces and a portion of the top surface of the electrodes (150, 155).

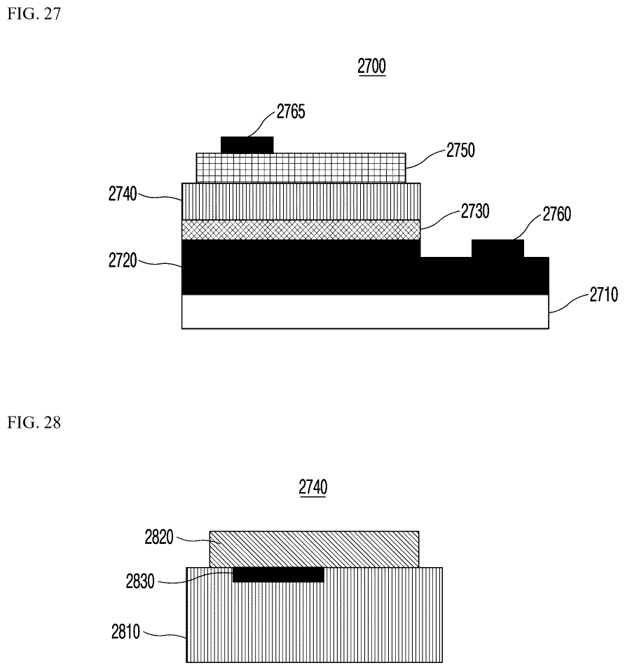

FIG. 27 is a diagram illustrating a configuration of a light-emitting device according to a fourth embodiment of the present invention.

Referring to FIG. 27, a light-emitting device (2700) according to the fourth embodiment of the present invention includes a substrate (2710), an n-type cladding layer (2720), an active layer (2730), a p-type semiconductor layer (2740), a transparent electrode (2750), and electrodes (2760, 2765). The substrate (2710), the n-type cladding layer (2720), and the active layer (2730) may be implemented with the same configurations as the substrate (110), the n-type cladding layer (120), and the active layer (130), and may perform the same operations.

The p-type semiconductor layer (2740) is deposited on the active layer (2730) and provides holes to the active layer (2730). In this case, as the p-type semiconductor layer (2740) is implemented with the structure shown in FIG. 28, light can be prevented from being output toward the electrode (2765) disposed in a light-output direction (i.e., the electrode disposed farther from the substrate), thereby improving light output of the light-emitting device.

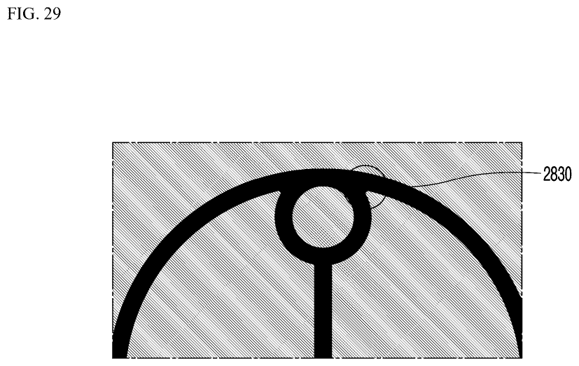

FIG. 28 is a diagram illustrating a configuration of a p-type semiconductor layer according to the fourth or fifth embodiment of the present invention, FIG. 29 is a plan view of the p-type semiconductor layer according to the fourth or fifth embodiment of the present invention, and FIG. 30 is a diagram comparing light efficiency between the light-emitting device according to the fourth embodiment of the present invention and a conventional light-emitting device.

Referring to FIG. 28, the p-type semiconductor layer (2740) according to the fourth or fifth embodiment of the present invention includes a p-type cladding layer (2810) and a p-type oxide layer (2820). The p-type cladding layer (2810) and the p-type oxide layer (2820) may be implemented with the same configurations as the p-type cladding layer (210) and the internal-strain relaxation layer (220), respectively, and may perform the same operations.

Meanwhile, in a region of the p-type cladding layer (2810), more specifically, directly below a region in which the electrode (2765) is to be disposed, a current-flow blocking portion (2830) is formed to have an area equal to or larger than an area of the electrode (2765). The current-flow blocking portion (2830) is formed through plasma treatment using oxygen or a gas containing oxygen, or through an ion/electron implantation process. Such processing is performed on the p-type cladding layer (2810) at a position aligned with a center of the electrode (2765) and over an area equal to or larger than the entire footprint area of the electrode (2765).

When plasma treatment or an ion/electron implantation process is performed on the p-type cladding layer (2810), physical properties of the p-type cladding layer (2810)—mainly properties affecting current flow or electrical characteristics—are changed to impede the flow of current (holes). In the processed region, the flow of current (here, holes) is impeded. Thereafter, when the p-type oxide layer (2820) is deposited on the p-type cladding layer (2810) whose physical properties have been changed, components constituting the p-type oxide layer (2820) affect the region of the p-type cladding layer (2810) with changed physical properties, thereby completing the current-flow blocking portion (2830) in the p-type cladding layer (2810). This can be clearly confirmed in FIG. 29. Referring to FIG. 29, as the p-type oxide layer (2820) is deposited on the p-type cladding layer (2810), it can be confirmed that the current-flow blocking portion (2830) is formed at a boundary between the two layers (2810, 2820). The current-flow blocking portion (2830) blocks most of current or completely blocks current.

Since the current-flow blocking portion (2830) is formed directly below the electrode (2765) over an area at least equal thereto, in delivering holes from the p-type cladding layer (2810) to the active layer (2730), holes are delivered to substantially all regions of the active layer (2730) except for the region in which the current-flow blocking portion (2830) is formed. Accordingly, when light is emitted by recombination of holes and electrons in the active layer (2730), light generated in regions other than the region where the electrode (2765) is located can freely exit the active layer without significant interference by the electrode (2765). As can be confirmed in FIG. 30, it can be confirmed that the light output of the light-emitting device (2700) is improved by approximately about 7% compared to a conventional light-emitting device.

Referring again to FIG. 27, the transparent electrode (2750) is stacked on the p-type semiconductor layer (2740), more specifically on the p-type oxide layer (2820), to supply current to the p-type semiconductor layer (2740). In order to supply current (holes) from the p-type semiconductor layer (2740) to substantially the entire region of the active layer (2730) except for the current-flow blocking portion (2830), the transparent electrode (2750) having excellent electrical conductivity and high transparency is stacked on the p-type oxide layer (2820). The transparent electrode (2750) may be implemented as ITO, NiO, GaZnO, InZnO, or InGaZnO so as to provide transparency and excellent electrical conductivity.

The electrodes (2760, 2765) are formed on the n-type cladding layer (2720) and on the transparent electrode (2750), respectively, to supply current to the respective components (2720, 2750). The electrode (2760) is formed on the n-type cladding layer (2720) exposed to the outside by etching, and the electrode (2765) is formed on the transparent electrode (2750). The electrodes (2760, 2765) may be implemented with one or more metals selected from Al, Ag, Cr, Cu, Mo, Ni, Pd, Ti, and W, or alloys thereof.

As the light-emitting device (2700) includes the above-described configuration, excellent light output can be secured by minimizing light irradiated toward the electrode (2765).

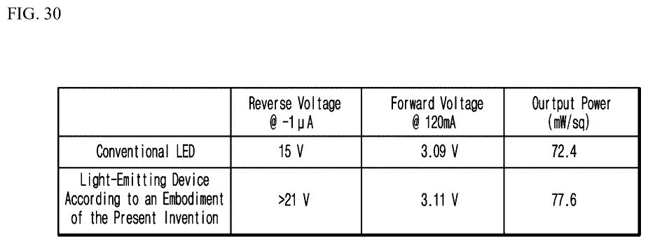

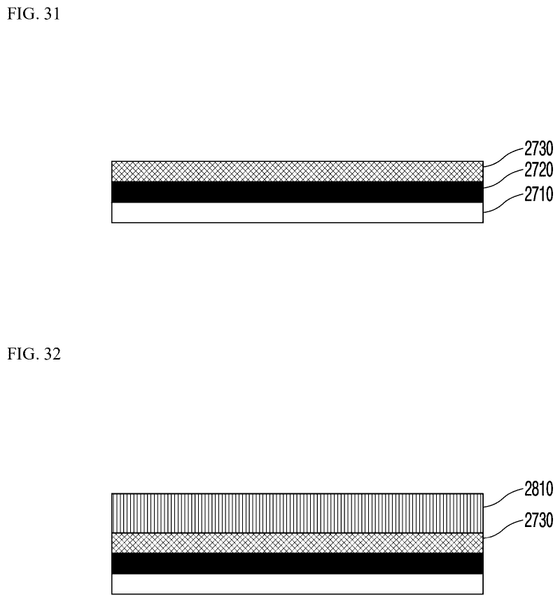

FIGS. 31 to 37 are diagrams illustrating a manufacturing process of a light-emitting device according to the fourth embodiment of the present invention. Manufacturing of the light-emitting device (2700) may be performed by a light-emitting-device manufacturing apparatus.

Referring to FIGS. 31 and 32, an n-type cladding layer (2720), an active layer (2730), and a p-type cladding layer (2810) are sequentially deposited on the substrate (2710).

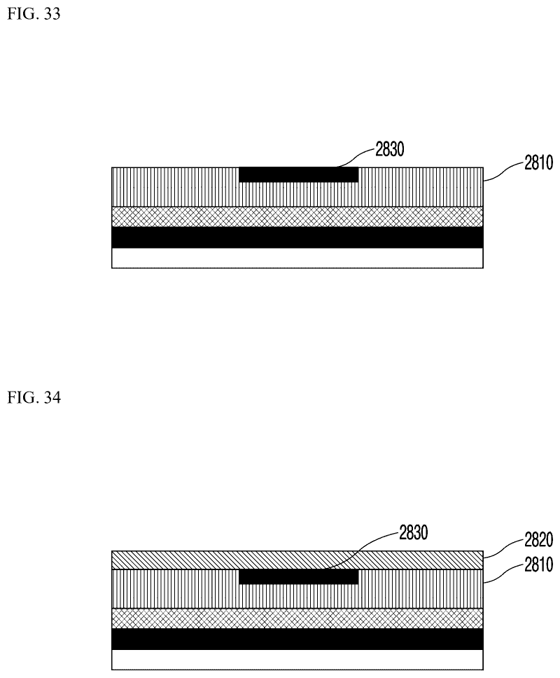

Referring to FIG. 33, after the p-type cladding layer (2810) is deposited, plasma treatment or an ion/electron implantation process is performed on a region in which the current-flow blocking portion (2830) is to be formed (i.e., directly below the electrode (2765) over an area at least equal thereto).

Referring to FIG. 34, the p-type oxide layer (2820) is deposited on the p-type cladding layer (2810). Accordingly, the current-flow blocking portion (2830) is formed in the p-type cladding layer (2810).

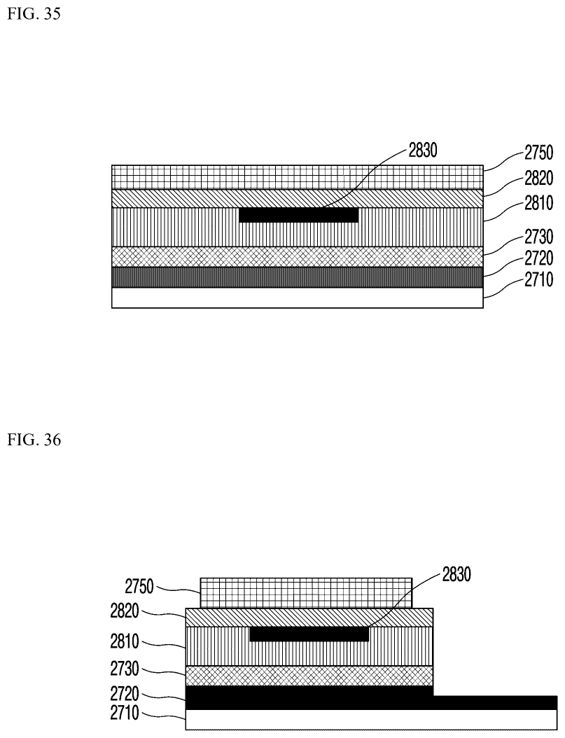

Referring to FIG. 35, the transparent electrode (2750) is stacked on the p-type oxide layer (2820).

Referring to FIG. 36, mesa-type etching is performed from the transparent electrode (2750) to a position of the n-type cladding layer (2720).

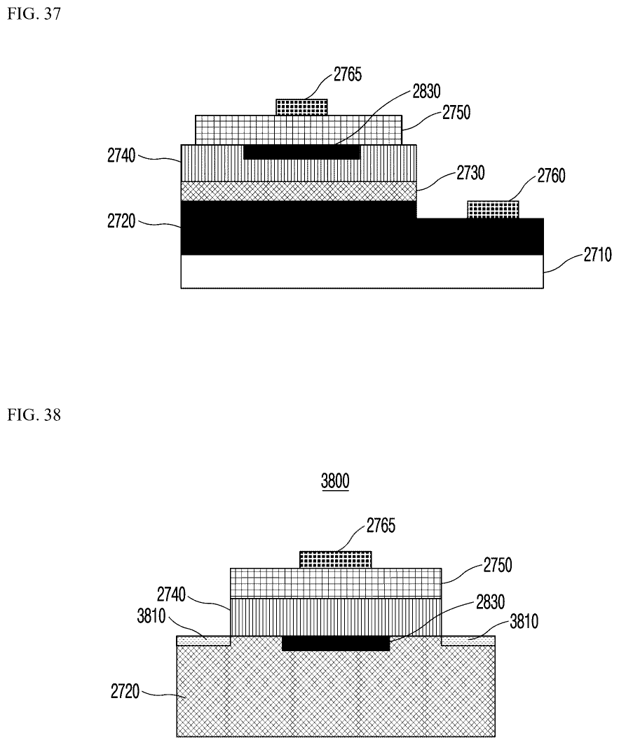

Referring to FIG. 37, as etching is performed, the electrode (2760) is formed on the n-type cladding layer (2720) exposed to the outside, and the electrode (2765) is formed on the transparent electrode (2750).

FIG. 38 is a diagram illustrating a configuration of a light-emitting device according to a fifth embodiment of the present invention.

Referring to FIG. 38, a light-emitting device (3800) according to the fifth embodiment of the present invention may further include leakage-current prevention portions (3810) in the p-type cladding layer (2810).

The p-type cladding layer (2810) in the light-emitting device (3800) may further include the leakage-current prevention portions (3810) at both ends. When the light-emitting device has a mesa structure, there may be a problem in which unintended current is injected into the p-type cladding layer (2810) or the like in an edge region of the mesa.

To prevent such a problem, the p-type cladding layer (2810) may further include the leakage-current prevention portions (3810) at both ends. As described above with reference to FIG. 36, when mesa-type etching is performed from the transparent electrode (2750) to a position of the n-type cladding layer (2720) and a side surface of the p-type cladding layer (2810) is exposed to the outside, additional plasma treatment using oxygen or a gas containing oxygen may be performed. Even when such plasma treatment is performed, physical properties of the p-type oxide layer (2820) (mainly properties affecting current flow or electrical characteristics) do not change, and only physical properties of the p-type cladding layer (2810) change. Accordingly, in a region of the p-type cladding layer (2810) that is not fully exposed to the outside because the p-type oxide layer (2820) is deposited thereon, no change in physical properties occurs; however, in side (end) portions exposed to the outside by etching and in a predetermined-area region therefrom, physical properties change occurs. The region having the predetermined area from both ends of the p-type cladding layer (2810) is implemented as the leakage-current prevention portion (3810) through the above-described process, and, similarly to the current-flow blocking portion (2830), impedes the flow of current.

The p-type cladding layer (2810) may further include leakage-current prevention portions (3810), thereby blocking the occurrence of leakage current toward both end portions and further improving the light output of the light-emitting device (3800).

The above description is merely a description of the technical spirit of the present embodiment, and those skilled in the art may change and modify the present embodiment in various ways without departing from the essential characteristic of the present embodiment. Accordingly, the embodiments should not be construed as limiting the technical spirit of the present embodiment, but should be construed as describing the technical spirit of the present embodiment. The technical spirit of the present embodiment is not restricted by the embodiments. The range of protection of the present embodiment should be construed based on the following claims, and all of technical spirits within an equivalent range of the present embodiment should be construed as being included in the scope of rights of the present embodiment.

What is claimed is:

1. A light-emitting device, comprising:
a substrate;
an n-type cladding layer deposited on the substrate and implemented with a semiconductor material doped with an n-type dopant;
an active layer deposited on the n-type cladding layer, in which holes and electrons provided from the n-type cladding layer recombine to generate light;
a p-type semiconductor layer deposited on the active layer and providing holes to the active layer;
a protective layer implemented with a material in which a light transmittance in a visible-wavelength band and an electrical conductivity are respectively at least a preset first reference value and at least a preset second reference value, the protective layer being deposited on the p-type semiconductor layer to protect the p-type semiconductor layer from outside; and
electrodes respectively formed on the n-type cladding layer and on the protective layer.

2. The light-emitting device of claim 1, wherein the n-type cladding layer is implemented as any one of n-type GaN, n-type InGaN, n-type AlGaN, and n-type AlInGaN, or is implemented as a combination thereof.

3. The light-emitting device of claim 1, wherein the p-type semiconductor layer mitigates internal strain generated when deposited on the active layer.

4. The light-emitting device of claim 1, wherein the p-type semiconductor layer is in ohmic contact with the protective layer.

5. The light-emitting device of claim 1, wherein the protective layer is implemented as ITO, NiO, GaZnO, InZnO, InGaZnO, or graphene.

6. The light-emitting device of claim 1, wherein the electrode is implemented with at least one metal selected from Al, Ag, Cr, Cu, Mo, Ni, Pd, Ti, and W, or an alloy thereof.

7. A method of manufacturing a light-emitting device, the method comprising:
a deposition process of sequentially depositing, on a substrate, an n-type cladding layer, an active layer, a p-type semiconductor layer, and a protective layer;
an etching process of etching a portion of one side surface region of the n-type cladding layer, the active layer, the p-type semiconductor layer, and the protective layer, wherein the etching proceeds vertically from the protective layer to a portion of the n-type cladding layer;
and a forming process of forming a first electrode on the protective layer and forming a second electrode on the n-type cladding layer exposed to outside by the etching process.

8. The method of claim 7, wherein the n-type cladding layer is deposited by an epitaxy single-crystal deposition method.

9. The method of claim 7, wherein the p-type semiconductor layer increases a hole concentration injected into the active layer and decreases internal strain formed in the active layer.

10. The method of claim 7, wherein the protective layer is implemented with a material in which a light transmittance in a visible-wavelength band and an electrical conductivity are respectively at least a preset first reference value and at least a preset second reference value.

11. The method of claim 10, wherein the protective layer is deposited by physical vapor deposition (PVD), chemical vapor deposition (CVD), e-beam deposition, or sputtering.

12. The method of claim 7, wherein the first electrode is implemented with a metal having a reflectance of at least a preset reference value.
